(19) United States
(12) Patent Application Publication
(10) Pub. No.: US 2024/0090165 A1
(43) Pub. Date: Mar. 14, 2024

(54) DEVICE FOR LIQUID COOLING OF NETWORK INTERFACE DEVICES

(71) Applicant: Mellanox Technologies Ltd., Yokneam (IL)

(72) Inventors: Oren Weltsch, Yokneam (IL); Igal Gutman, Yokneam (IL); Rom Becker, Yokneam (IL); Shay Zaretsky, Yokneam (IL); Ayal Shabtay, Yokneam (IL); Michal Shlomai Hermon, Yokneam (IL); Kfir Katz, Yokneam (IL)

(73) Assignee: Mellanox Technologies Ltd., Yokneam (IL)

(21) Appl. No.: 17/944,638

(22) Filed: Sep. 14, 2022

(51) Int. Cl. H05K 7/20; H04Q 1/02

(52) U.S. Cl. CPC H05K 7/20254; H04Q 1/035; H05K 7/20272; H05K 7/2049

(57) ABSTRACT

An electronic device may include a receptacle cage comprising a longitudinal aperture extending along a portion of a top surface of the receptacle cage, a cooling body disposed directly on the top surface of the receptacle cage, wherein a longitudinal portion of a bottom surface of the cooling body is disposed within the longitudinal aperture on the top surface of the receptacle cage, a first conduit to deliver a liquid coolant into an interior of the cooling body, and a second conduit to deliver the liquid coolant from the interior of the cooling body.

### FIELD OF THE INVENTION

The present invention relates to the field of network systems and, more particularly, to devices for liquid cooling of network interface devices.

### BACKGROUND OF THE INVENTION

Typically, network devices, e.g., network switch devices, include receptacle cages configured to receive network interface devices, e.g., small form-factor pluggable (SFP) devices. In operation, network interface devices typically produce heat that may cause reduction in their performance. The receptacle cages are typically covered with one or more cover plates disposed on top of the receptacle cages. The network devices may include liquid cooled plates mounted on top of the cover plate to dissipate heat generated by the network interface devices. Typically, there is no direct contact between the liquid cooled plates and the receptacle cages. Typically, there is also no direct contact between the liquid cooled plates and the network interface devices disposed within the receptacle cages. In addition, there is typically only limited space for disposing the liquid cooled plates between the receptacle cages cover plate and other components of the network device. Accordingly, the liquid cooled plates may have limited dimensions, may pass limited flowrates of liquid coolant therethrough and thus may provide limited cooling to the network interface devices operating in the receptacle cages. However, current network interface devices may generate heat at relatively high rates, e.g., at 17 Watt or higher. In some cases, current cooling solutions may be not sufficient to efficiently cool current network interface devices.

### SUMMARY OF THE INVENTION

Some embodiments of the present invention provide an electronic device which may include: a receptacle cage including a longitudinal aperture extending along a portion of a top surface of the receptacle cage, a cooling body disposed directly on the top surface of the receptacle cage, wherein a longitudinal portion of a bottom surface of the cooling body is disposed within the longitudinal aperture on the top surface of the receptacle cage, a first conduit to deliver a liquid coolant into an interior of the cooling body, and a second conduit to deliver the liquid coolant from the interior of the cooling body. The cooling body may contain, within an interior thereof, a passage through which the liquid coolant is configured to flow. The longitudinal portion of the bottom surface of the cooling body may protrude into an interior of the receptacle cage through the longitudinal aperture. The receptacle cage may be configured to receive into its interior a network interface device, wherein the longitudinal portion of the bottom surface of the cooling body that protrudes into the interior of the receptacle cage may be configured to contact a top surface of the network interface device when the network interface device is received within the interior of the receptacle cage. The electronic device may include a thermal interface material disposed at least on the longitudinal portion of the bottom surface of the cooling body. The electronic device may include a spring clip configured to hold to the cooling body with respect to the receptacle cage. The cooling body may include an interior including a first longitudinal portion and a second longitudinal portion separated by an internal wall, and the internal wall may have an opening fluidically connecting the first and second longitudinal portions of the interior of the cooling body. The cooling body may include an inlet opening configured to provide an inflow of the liquid coolant into the first longitudinal portion of the interior. The cooling body may include an outlet opening configured to provide an outflow of the liquid coolant from the second longitudinal portion of the interior. The inlet and the outlet openings may be disposed at one end of the cooling body. The electronic device may be a network switch device.

Some embodiments of the present invention may provide an electronic device which may include a plurality of receptacle cages, each of which receptacle cages may include a longitudinal opening extending along a portion of a top surface thereof, a plurality of heat sink bodies configured to contain a liquid coolant, wherein each of the heat sink bodies is in direct contact with the top surface of one of the receptacle cages and covers the longitudinal opening of the respective receptacle cage, and a plurality of conduits interconnecting the heat sink bodies. A longitudinal portion of each of the heat sink bodies may be disposed within the longitudinal opening of the respective receptacle cage. A longitudinal portion of each of the heat sink bodies may protrude into an interior of the respective receptacle cage through the respective longitudinal opening. Each of the receptacle cages may be configured to receive into its interior a form factor device, wherein each of the heat sink bodies that protrudes into the interior of the respective receptacle cage may be configured to contact the respective form factor device when the respective form factor device is received within the interior of the respective receptacle cage. The electronic device may include a plurality of thermal contact enhancers (e.g. pads of thermal interface material), wherein each of the thermal contact enhancers may disposed on a longitudinal portion of one of the heat sink bodies that covers the longitudinal opening of the respective receptacle cage. The electronic device may include a plurality of spring clips, wherein each of the spring clips may be configured to hold one of the heat sink bodies with respect to the respective receptacle cages. Each of the heat sink bodies may include an internal wall that divides an interior of the respective heat sink body into a first longitudinal portion and a second longitudinal portion, and the internal wall may have an opening fluidically connecting the first and second longitudinal portions of the interior of the cooling body. Each of the heat sink bodies may include an inlet opening configured to provide an inflow of the liquid coolant into the first longitudinal portion of the interior. Each of the heat sink bodies may include an outlet opening configured to provide an outflow of the liquid coolant from the second longitudinal portion of the interior. The inlet and outlet openings of each of the heat sink bodies may be disposed at one end of the respective heat sink body. Each of the conduits may interconnect the outlet opening of one of the heat sink bodies with the inlet opening of an adjacent heat sink body.

Some embodiments of the present invention may provide an electronic device which may include: a plurality of receptacle cages, each of which receptacle cages including a longitudinal opening extending along a portion of a top surface thereof, a plurality of heat sink bodies configured to contain a liquid coolant, each of which heat sink bodies covering the longitudinal opening of one of the receptacle cages and being configured to contact a form factor device when the form factor device is received within the respective receptacle cage, and a plurality of conduits interconnecting the heat sink bodies.

### BRIEF DESCRIPTION OF THE DRAWINGS

For a better understanding of embodiments of the invention and to show how the same can be carried into effect, reference will now be made, purely by way of example, to the accompanying drawings in which like numerals designate corresponding elements or sections throughout.

In the accompanying drawings:

FIGS. 1A and 1B are perspective views of an electronic device, according to some embodiments of the invention;

FIGS. 2A and 2B are different exploded perspective views of a subset of receptacle cages, heat sink bodies, conduits and spring clips of the electronic device, according to some embodiments of the invention;

FIGS. 2C and 2D are different perspective views of the assembled subset of receptacle cages, heat sink bodies, conduits and spring clips of the electronic device, according to some embodiments of the invention;

FIG. 2E is a an enlarged perspective view of region A of FIG. 2C showing spring clips engaging with heat sink bodies and receptacle cages of the electronic device, according to some embodiments of the invention;

FIG. 2F is a an enlarged perspective view of region B of FIG. 2D showing the heat sink body disposed on the receptacle cage of the electronic device, according to some embodiments of the invention;

FIG. 2G is a cross-sectional view of the assembled structure of FIG. 2C taken along line CC of FIG. 2C showing the receptacle cage, the heat sink body and a network interface device disposed within the receptacle cage of the electronic device, according to some embodiments of the invention;

FIGS. 3A and 3B are different perspective views of the heat sink body, according to some embodiments of the invention;

FIG. 3C is a perspective view of a plurality of the heat sink bodies interconnected by the conduits, according to some embodiments of the invention; and

FIG. 4 is a perspective view of the heat sink body including a thermal contact enhancer, according to some embodiments of the invention.

It will be appreciated that, for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following description, various aspects of the present invention are described. For purposes of explanation, specific configurations and details are set forth in order to provide a thorough understanding of the present invention. However, it will also be apparent to one skilled in the art that the present invention can be practiced without the specific details presented herein. Furthermore, well known features can have been omitted or simplified in order not to obscure the present invention. With specific reference to the drawings, it is stressed that the particulars shown are by way of example and for purposes of illustrative discussion of the present invention only and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention can be embodied in practice.

Before at least one embodiment of the invention is explained in detail, it is to be understood that the invention is not limited in its application to the details of construction and the arrangement of the components set forth in the following description or illustrated in the drawings. The invention is applicable to other embodiments that can be practiced or carried out in various ways as well as to combinations of the disclosed embodiments. Also, it is to be understood that the phraseology and terminology employed herein is for the purpose of description and should not be regarded as limiting.

Some embodiments of the present invention may improve cooling of network interface devices that are disposed within receptacle cages of an electronic device. The electronic device, e.g., a network switch device, may include a plurality of receptacle cages disposed on a printed circuit board (PCB) of the electronic device. Each of the receptacle cages may include a longitudinal opening (e.g., aperture) formed through a top surface (e.g., top wall) of the receptacle cage and extending along a portion of the top surface of the receptacle cage. The electronic device may include a plurality of heat sink bodies (e.g., cooling bodies). Each of the heat sink bodies may contain a liquid coolant. Each of the heat sink bodies may include, within an interior thereof, a passage through which the liquid coolant may flow. Each of the heat sink bodies may be disposed directly on the top surface of one of the receptacle cages. Each of the heat sink bodies may cover the longitudinal opening of the respective receptacle cage. A longitudinal portion of a bottom surface of each of the heat sink bodies may be disposed within the longitudinal opening of the respective receptacle cage. Each of the heat sink bodies that protrudes into the interior of the respective receptacle cage may contact a network interface device when the network interface device is disposed within the interior of the respective receptacle cage. The electronic device may include a plurality of conduits interconnecting the heat sink bodies in series to each other.

In the prior art, the liquid cooled plates are disposed on, i.e., external to, the cover plate that covers the receptacle cages. Instead, in the inventive electronic device, the cover plate is eliminated, and the heat sink bodies are disposed directly on the receptacle cages, which provides greater space for accommodation of the heat sink bodies as compared to prior art. Accordingly, the heat sink bodies may have larger dimensions as compared to prior art liquid cooled plates. Therefore, due to the larger dimensions, the heat sink bodies may allow higher flowrates of the liquid coolant to pass therethrough as compared to prior art liquid cooled plates. While the liquid coolant flows through the heat sink bodies that are connected in series, the temperature of the liquid coolant is raised due to absorption of heat from the electronic device. Higher flowrates of the liquid coolant through the heat sink bodies may result in lower raise of the temperature of the liquid coolant, as compared to prior art liquid cooled plates passing lower flowrates of the liquid coolant therethrough. Accordingly, more heat sink bodies may be connected in series to the same liquid coolant source as compared to prior art liquid cooled plates. For example, sixteen heat sink bodies may be connected in series to the same liquid coolant source in the inventive electronic device, as compared to four liquid cooled plates in prior art. Connection of more heat sink bodies to the same liquid coolant source may provide a more compact, less complex and cheaper cooling solution as compared to prior art. Furthermore, the heat sink bodies may directly contact the network interface devices and thus may remove at higher rates the heat generated by the network interface devices as compared to prior art liquid cooled plates that themselves have no direct contact with the network interface devices.

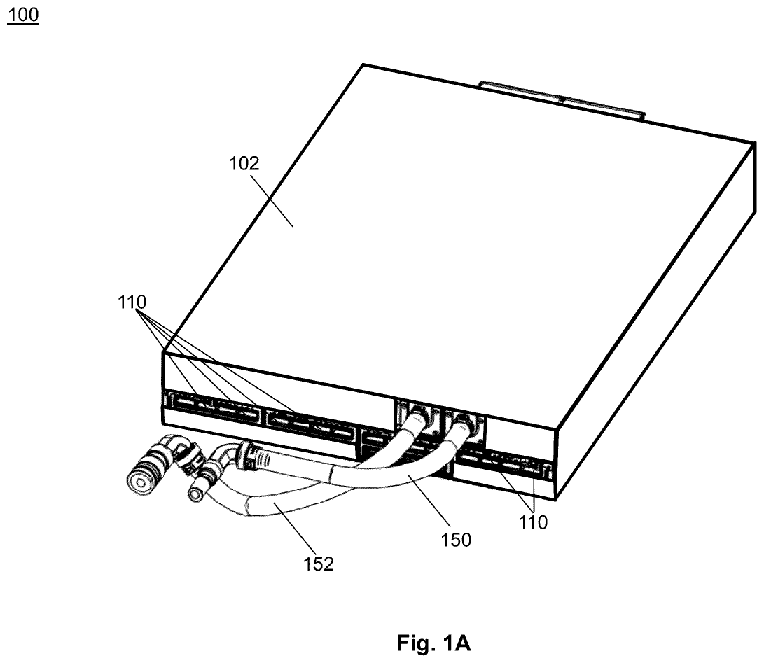

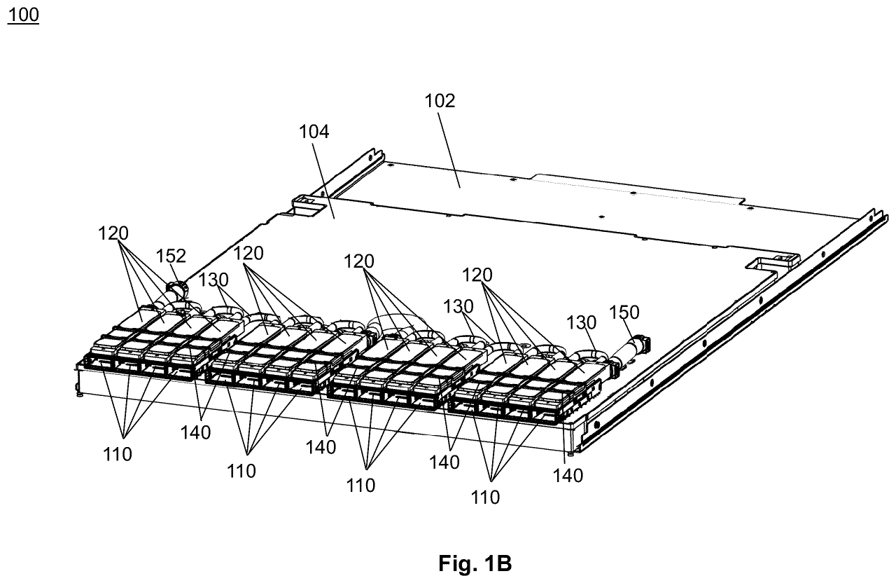

Reference is now made to FIGS. 1A and 1B, which are perspective views of an electronic device 100, according to some embodiments of the invention. FIG. 1B shows the same electronic device 100 as in FIG. 1A but does not show portions of housing 102 of electronic device 100 in order to expose the interior of electronic device 100.

Electronic device 100 may include a housing 102 to accommodate components of electronic device 100 (e.g., as shown in FIGS. 1A and 1B). Electronic device 100 may include a plurality of receptacle cages 110 (e.g., as shown in FIGS. 1A and 1B). Receptacle cages 110 may be disposed on, e.g., a printed circuit board (PCB) 104 of electronic device 100 (e.g., as shown in FIG. 1B). Each of receptacle cages 110 may receive a network interface device (not shown in FIG. 1). Network interface devices may, for example, include form factor devices, such as small form factor pluggable (SFP) devices (e.g., quad SFP (QSFP) devices, octal SFP (OSFP) devices) or any other suitable SFP devices known in the art.

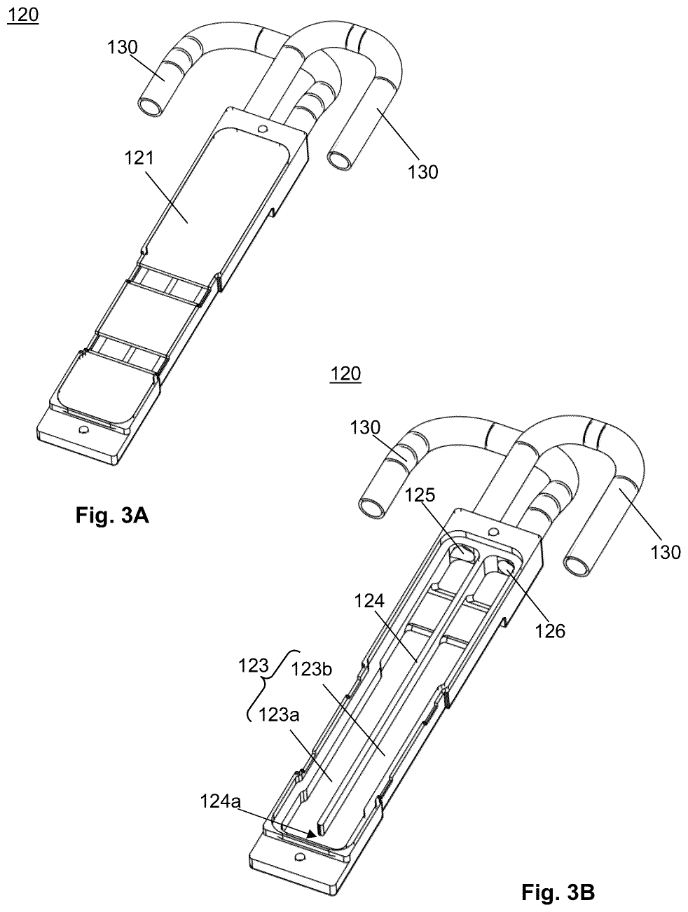

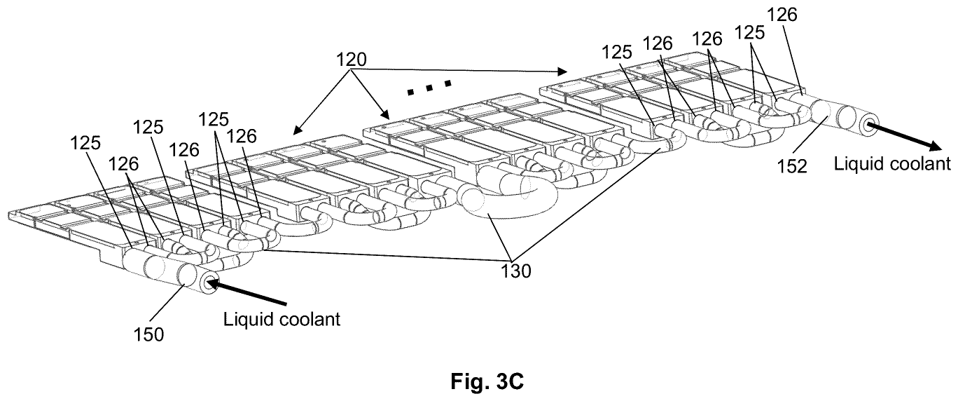

Electronic device 100 may include a plurality of heat sink bodies (e.g., cooling bodies) 120 (e.g., as shown in FIG. 1B). Each of heat sink bodies 120 may contain a liquid coolant. Each of heat sink bodies 120 may include, within an interior thereof, a passage through which the liquid coolant may flow (e.g., as described below with respect to FIGS. 3A and 3B). Each of heat sink bodies 120 may be disposed directly on one of receptacle cages 110 (e.g., as shown in FIG. 1B).

While sixteen receptacle cages 110 and heat sink bodies 120 are shown in FIG. 1B, electronic device 100 may include any number of receptacle cages 110 and heat sink bodies 120. For example, electronic device 100 may include more than sixteen receptacle cages 110 and heat sink bodies 120 (e.g., thirty-two receptacle cages 110 and heat sink bodies 120). Electronic device 100 may include two or more subgroups of receptacle cages 110 and heat sink bodies 120, wherein at least two of the subgroups may be disposed at opposing sides of PCB 104 with respect to each other.

Electronic device 100 may include conduits 130 interconnecting heat sink bodies 120 (e.g., as shown in FIG. 1B). Conduits 130 may interconnect heat sink bodies 120 in series to each other. A subgroup of heat sink bodies 120 connected in series may be connected to and may receive the liquid coolant from the same liquid coolant source. In the example of FIG. 1, a subgroup of sixteen in series connected heat sink bodies 120 is connected to the same liquid coolant source. For example, as shown in FIG. 1B, a first heat sink body of heat sink bodies 120 may be connected to an inlet conduit 150 and may receive the liquid coolant from the liquid coolant source. The liquid coolant may flow sequentially through all heat sink bodies 120 in the subgroup and may exit externally from a last heat sink body in the subgroup of heat sink bodies 120 through an outlet conduit 152 connected to the last heat sink body in the subgroup. Inlet conduit 150 and outlet conduit 152 may extend externally from the interior of electronic device 100 (e.g., as shown in FIG. 1A). Inlet conduit 150 and outlet conduit 152 may be connected to suitable components of a liquid cooling infrastructure within a network data center.

Electronic device 100 may include a plurality of spring clips 140. Each of spring clips 140 may hold one of heat sink bodies 120 with respect to respective receptacle cage 110. Each of spring clips 140 may hold one of heat sink bodies 120 with respect to respective receptacle cage 110 while providing a certain measure of movement of respective heat sink body 120 with respect to respective receptacle cage 110 in a direction that is perpendicular (or substantially perpendicular) to PCB 104. Spring clips 140 may ensure tight contact of heat sink bodies 120 with the network interface devices when the network interface devices are disposed in receptacle cages 110. Some of spring clips 140 may be interconnected to hold a subset of heat sink bodies 120 as a single unit with respect to a respective subset of receptacle cages 110. In the example of FIG. 1, each four spring clips 140 are interconnected to hold as a single unit a subset of four heat sink bodies 120 to the respective subset of four receptacle cages 110.

Electronic device 100 may be a network switch device or any other suitable network device known in the art.

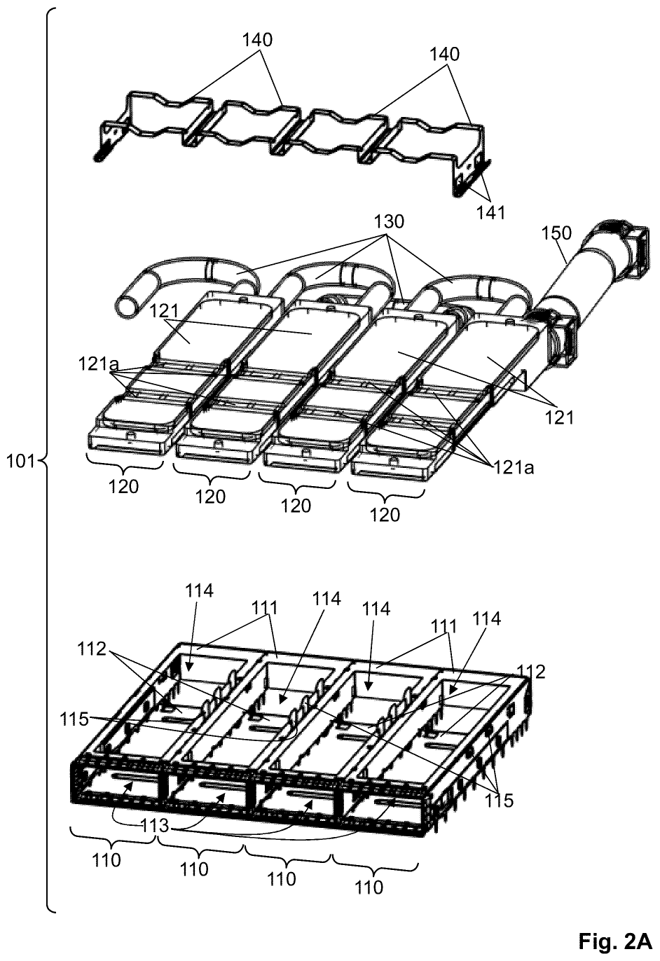

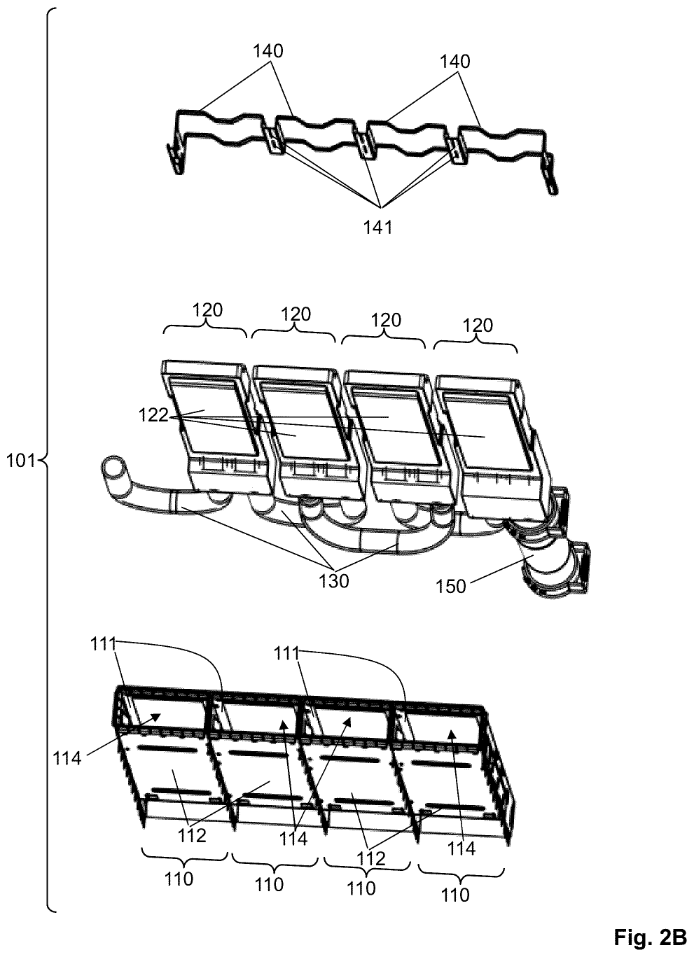

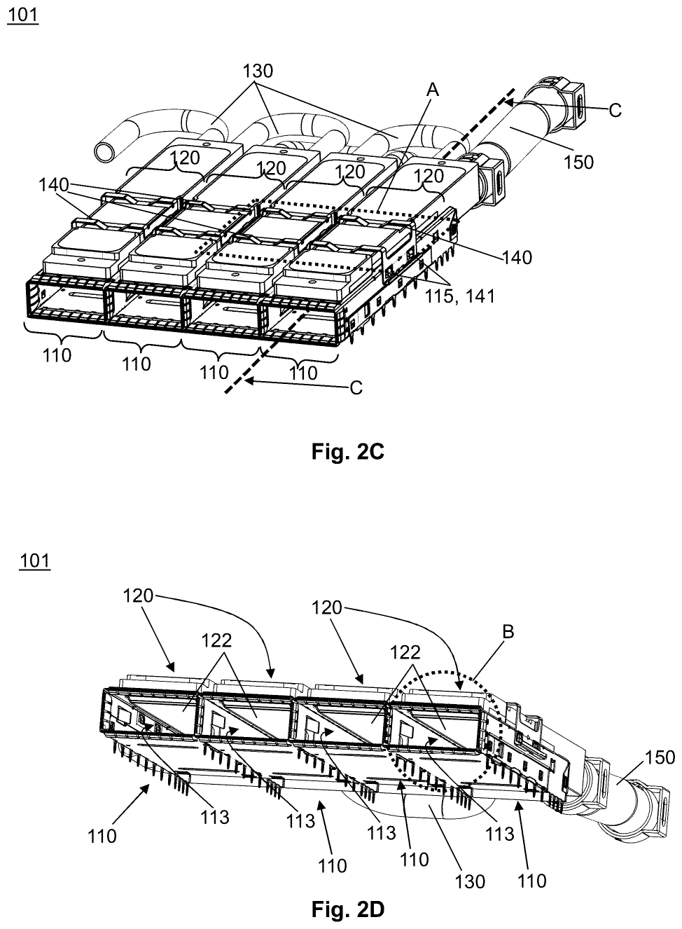

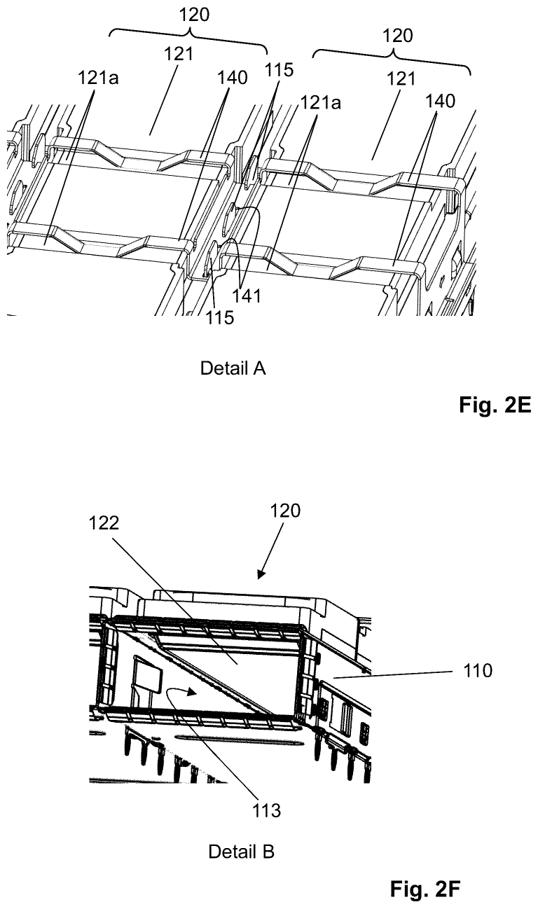

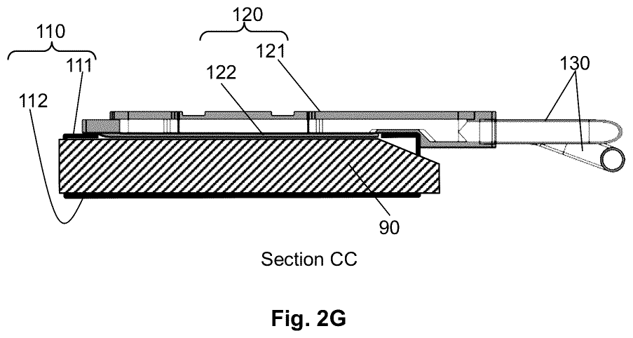

Reference is now made to FIGS. 2A and 2B, which are different exploded perspective views of a subset 101 of receptacle cages 110, heat sink bodies 120, conduits 130 and spring clips 140 of electronic device 100, according to some embodiments of the invention.

Reference is also made to FIGS. 2C and 2D, which are different perspective views of assembled subset 101 of receptacle cages 110, heat sink bodies 120, conduits 130 and spring clips 140 of electronic device 100, according to some embodiments of the invention.

Reference is also made to FIG. 2E, which shows an enlarged view of region A of FIG. 2C showing spring clips 140 engaging with heat sink bodies 120 and receptacle cages 110 of electronic device 100, according to some embodiments of the invention.

Reference is also made to FIG. 2F, which shows an enlarged view of region B of FIG. 2D showing heat sink body 120 disposed on receptacle cage 110 of electronic device 100, according to some embodiments of the invention.

Reference is further made to FIG. 2G, which is a cross-sectional view along line CC of FIG. 2C showing receptacle cage 110, heat sink body 120 and a network interface device 90 disposed within receptacle cage 110 of electronic device 100, according to some embodiments of the invention.

Each of receptacle cages 110 may include a top surface 111 configured to face away from PCB 104 (for simplicity, PCB 104 is not shown in FIGS. 2A-2F), a bottom surface 112 opposing top surface 111 and configured to face PCB 104, and an interior 113 (e.g., as shown in FIGS. 2A and 2B). Each of receptacle cages 110 may include a longitudinal opening (e.g., longitudinal aperture) 114 formed through top surface 111 and extending along at least a portion of top surface 111 of respective receptacle cage 110. Longitudinal opening 114 of each of receptacle cages 110 may have, for example, a rectangular shape.

Each of heat sink bodies 120 may have a top surface 121 configured to face away from respective receptacle cage 110, and a bottom surface 122 opposing top surface 121 and configured to face respective receptacle cage 110 (e.g., as shown in FIGS. 2A and 2B). When assembled, bottom surface 122 of each of heat sink bodies 120 may be disposed directly onto top surface 111 of respective receptacle cage 110 (e.g., as shown in FIGS. 2C and 2D). A longitudinal portion of bottom surface 122 of each of heat sink bodies 120 may cover longitudinal opening 114 in top surface 111 of respective receptacle cage 110 (e.g., as shown in FIGS. 2D and 2F). A longitudinal portion of bottom surface 122 of each of heat sink bodies 120 may be disposed within longitudinal opening 114 on top surface 111 of respective receptacle cage 110 (e.g., as shown in FIGS. 2D and 2F). A longitudinal portion of bottom surface 122 of each of heat sink bodies 120 that is disposed within longitudinal opening 114 may protrude into interior 113 of respective receptacle cage 111 through longitudinal opening 114 of respective receptacle cage 111 (e.g., as shown in FIGS. 2D and 2F). A longitudinal portion of bottom surface 122 of each of heat sink bodies 120 that protrudes into interior 113 of respective receptacle cage 111 may contact a network interface device 90 when the network interface device 90 is disposed within interior 113 of a respective receptacle cage 110 (e.g., as shown in FIG. 2G).

Spring clips 140 may hold heat sink bodies 120 in place with respect to receptacle cages 110. When assembled, spring clips 140 may engage with heat sink bodies 120 and with receptacle cages 110 to hold heat sink bodies 120 in place with respect to receptacle cages 110. For example, heat sink bodies 120 may include transverse indents 121a that are formed on their top surfaces 121 and that are configured to engage with spring clips 140 (e.g., as shown in FIGS. 2A, 2C and 2E). Receptacle cages 110 may include protrusions 115 extending from receptacle cages 110 (e.g., disposed on top surfaces 111 of receptacle cages 110, e.g., in-between receptacle cages 110, and/or on side surfaces of receptacle cages 110) and configured to engage with mating slots 141 formed on spring clips 140 (e.g., as shown in FIGS. 2A and 2E). Some of spring clips 140 may be interconnected to hold the subset of heat sink bodies 120 with respect to the respective subset of receptacle cages 110 as a single unit. For example, each four spring clips 140 are interconnected so as to hold as a single unit a subset of four heat sink bodies 120 to the respective subset of four receptacle cages 110 (e.g., as shown in FIGS. 2A, 2B and 2C). Any other suitable engagement means may be used to engage spring clips 140 with receptacle cages 110 and heat sink bodies 120.

Reference is now made to FIGS. 3A and 3B, which are perspective views of heat sink body 120, according to some embodiments of the invention. FIG. 3B shows the same view of heat sink body 120 as in FIG. 3A but with a portion of the top surface 121 of heat sink body 120 removed so as to expose an interior 123 of heat sink body 120.

Each of heat sink bodies 120 may include, within its interior 123, an internal wall 124 to divide interior 123 of respective heat sink body 120 into a first longitudinal portion 123a and a second longitudinal portion 123b. Internal wall 124 may include an opening 124a fluidically connecting first longitudinal portion 123a and second longitudinal portion 123b. Each of heat sink bodies 120 may include an inlet opening 125 to provide an inflow of the liquid coolant into first longitudinal portion 123a of its interior 123. Each of heat sink bodies 120 may include an outlet opening 126 to provide an outflow of the liquid coolant from second longitudinal portion 123b of its interior 123. Inlet opening 125 and outlet opening 126 of each of heat sink bodies 120 may be disposed at one end of respective heat sink body 120 (e.g., as shown in FIGS. 3A and 3B). Inlet opening 125, first longitudinal portion 123a, wall opening 124a, second longitudinal portion 123b and outlet opening 126 may together form, within interior 123 of respective heat sink body 120, a passage through which the liquid coolant may flow.

Reference is now made to FIG. 3C, which is a perspective view of a plurality of heat sink bodies 120 interconnected by conduits 130, according to some embodiments of the invention.

Conduits 130 may interconnect heat sink bodies 120 to each other in series. All conduits 130 may be disposed at the same side of heat sink bodies 120. Each of conduits 130 may interconnect the outlet opening 126 of one of heat sink bodies 120 with the inlet opening 125 of an adjacent one of heat sink bodies 120 (e.g., as shown in FIG. 3C). In the example of FIG. 3C, sixteen heat sink bodies 120 are connected to each other in series. The liquid coolant may be supplied to the first of heat sink bodies 120 through inlet conduit 150, may flow through interiors 123 of heat sink bodies 120, and may exit externally from the last of heat sink bodies 120 through outlet conduit 152.

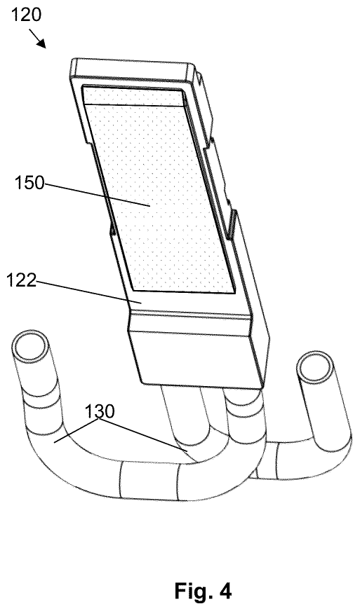

Reference is now made to FIG. 4, which is a perspective view of heat sink body 120 including a thermal contact enhancer 150, according to some embodiments of the invention.

Each of heat sink bodies 120 may include, disposed on its bottom surface 122, a thermal contact enhancer 150. Thermal contact enhancer 150 may include a pad of thermal interface material (e.g., as shown in FIG. 4). Thermal contact enhancer 150 may be disposed on a portion of bottom surface 122 that is configured to contact the network interface device. Thermal interface material may, for example, include phase change material or any other suitable thermal interface material known in the art. Thermal contact enhancer 150 may enhance thermal coupling between heat sink bodies 120 and the network interface devices when heat sink bodies 120 contact the network interface devices.

Advantageously, unlike in the prior art, in which the liquid cooled plates are disposed on the cover plate that covers the receptacle cages of the electronic device, heat sink bodies 120 are disposed directly on receptacle cages 110 of electronic device 100, which provides greater space for accommodation of heat sink bodies 120 as compared to the prior art. Accordingly, heat sink bodies 120 may have larger dimensions as compared to prior art liquid cooled plates. Therefore, heat sink bodies 120 may pass therethrough higher flowrates of the liquid coolant as compared to prior art liquid cooled plates. While the liquid coolant flows through the heat sink bodies 120 connected in series, the temperature of the liquid coolant is raised due to absorption of heat from the electronic device. Higher flowrates of the liquid coolant through heat sink bodies 120 may result in lower raise of the temperature of the liquid coolant, as compared to prior art liquid cooled plates that pass lower flowrates of the liquid coolant therethrough. Accordingly, more heat sink bodies 120 may be connected in series to the same liquid coolant source than in the prior art. For example, sixteen heat sink bodies 120 may be connected in series to the same liquid coolant source in electronic device 120 as compared to four liquid cooled plates in prior art. Connection of more heat sink bodies 120 to the same liquid coolant source may provide more compact, less complex and cheaper cooling solution as compared to prior art.

Furthermore, heat sink bodies 120 directly contact the network interface devices and thus may remove at higher rates the heat generated by the network interface devices as compared to prior art liquid cooled plates that themselves have no direct contact with the network interface devices.

In the prior art, the receptacle cages are typically covered with the cover plate on top of which the liquid cooled plates are mounted. The cover plate may cause a drop of temperature between the network interface devices and the liquid cooled plates which may reduce the efficiency of cooling of the network interface devices. Instead, heat sink bodies 120 directly contact the network interface devices, without having cover plate disposed between heat sink bodies 120 and the network interface devices, thus eliminating the drop of temperature present in the prior art and increasing the efficiency of cooling of the network interface devices as compared to the prior art.

Moreover, heat sink bodies 120 are held with respect to receptacle cages 110 using spring clips 140. Spring clips 140 are positioned externally to heat sink bodies 120 and do not occupy any volume within interiors 123 of heat sink bodies 120. Thus, spring clips 140 do not affect the flowrate of the liquid coolant that may pass through heat sink bodies 120. Instead, in prior art, the liquid cooled plates are connected directly to the cover plate, e.g., using screws protruding through the interiors of the liquid cooled plates. Because the screws occupy significant internal volume the prior art liquid cooled plates, they thus reduce the flowrate of the liquid coolant that may pass through the liquid cooled plates.

In the above description, an embodiment is an example or implementation of the invention. The various appearances of “one embodiment”, “an embodiment”, “certain embodiments” or “some embodiments” do not necessarily all refer to the same embodiments. Although various features of the invention can be described in the context of a single embodiment, the features can also be provided separately or in any suitable combination. Conversely, although the invention can be described herein in the context of separate embodiments for clarity, the invention can also be implemented in a single embodiment. Certain embodiments of the invention can include features from different embodiments disclosed above, and certain embodiments can incorporate elements from other embodiments disclosed above. The disclosure of elements of the invention in the context of a specific embodiment is not to be taken as limiting their use in the specific embodiment alone. Furthermore, it is to be understood that the invention can be carried out or practiced in various ways and that the invention can be implemented in certain embodiments other than the ones outlined in the description above.

Although embodiments of the invention are not limited in this regard, the terms “plurality” and “a plurality” as used herein can include, for example, “multiple” or “two or more”. The terms “plurality” or “a plurality” can be used throughout the specification to describe two or more components, devices, elements, units, parameters, or the like. The term set when used herein can include one or more items.

The invention is not limited to those diagrams or to the corresponding descriptions. For example, flow need not move through each illustrated box or state, or in exactly the same order as illustrated and described. Meanings of technical and scientific terms used herein are to be commonly understood as by one of ordinary skill in the art to which the invention belongs, unless otherwise defined. While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

1. An electronic device comprising:
a receptacle cage comprising a longitudinal aperture extending along a portion of a top surface of the receptacle cage;
a cooling body disposed directly on the top surface of the receptacle cage, wherein a longitudinal portion of a bottom surface of the cooling body is disposed within the longitudinal aperture on the top surface of the receptacle cage; and
a first conduit to deliver a liquid coolant into an interior of the cooling body, and a second conduit to deliver the liquid coolant from the interior of the cooling body.

2. The electronic device of claim 1, wherein the cooling body contains, within the interior thereof, a passage through which the liquid coolant is configured to flow.

3. The electronic device of claim 1, wherein the longitudinal portion of the bottom surface of the cooling body protrudes into an interior of the receptacle cage through the longitudinal aperture.

4. The electronic device of claim 1,
wherein the receptacle cage is configured to receive a network interface device, and
wherein the longitudinal portion of the bottom surface of the cooling body is configured to contact a top surface of the network interface device when the network interface device is received within the receptacle cage.

5. The electronic device of claim 1, further comprising a thermal interface material disposed at least on the longitudinal portion of the bottom surface of the cooling body.

6. The electronic device of claim 1, further comprising a spring clip configured to hold the cooling body with respect to the receptacle cage.

7. The electronic device of claim 1, wherein the cooling body comprises:
an interior comprising a first longitudinal portion and a second longitudinal portion separated by an internal wall, the internal wall having an opening fluidically connecting the first and second longitudinal portions of the interior;
an inlet opening configured to provide an inflow of the liquid coolant into the first longitudinal portion of the interior; and
an outlet opening configured to provide an outflow of the liquid coolant from the second longitudinal portion of the interior.

8. The electronic device of claim 8, wherein the inlet and the outlet openings are disposed at one end of the cooling body.

9. The electronic device of claim 1, wherein the electronic device is a network switch device.

10. An electronic device comprising:
a plurality of receptacle cages, each of the receptacle cages comprising a longitudinal opening extending along a portion of a top surface thereof;
a plurality of heat sink bodies configured to contain a liquid coolant, wherein each of the heat sink bodies is in direct contact with the top surface of one of the receptacle cages and covers the longitudinal opening of the respective receptacle cage; and
a plurality of conduits interconnecting the heat sink bodies.

11. The electronic device of claim 10, wherein a longitudinal portion of each of the heat sink bodies is disposed within the longitudinal opening of the respective receptacle cage.

12. The electronic device of claim 10, wherein a longitudinal portion of each of the heat sink bodies protrudes into an interior of the respective receptacle cage through the respective longitudinal opening.

13. The electronic device of claim 10,
wherein each of the receptacle cages is configured to receive a form factor device, and
wherein each of the heat sink bodies is configured to contact the respective form factor device when the respective form factor device is received within the respective receptacle cage.

14. The electronic device of claim 10, further comprising a plurality of thermal contact enhancers, each of the thermal contact enhancers being disposed on a longitudinal portion of one of the heat sink bodies that covers the longitudinal opening of the respective receptacle cage.

15. The electronic device of claim 10, further comprising a plurality of spring clips, wherein each of the spring clips is configured to hold one of the heat sink bodies with respect to the respective receptacle cages.

16. The electronic device of claim 10, wherein each of the heat sink bodies comprises:
an internal wall to divide an interior of the respective heat sink body into a first longitudinal portion and a second longitudinal portion, the internal wall having an opening fluidically connecting the first and second longitudinal portions of the interior;
an inlet opening configured to provide an inflow of the liquid coolant into the first longitudinal portion of the interior; and
an outlet opening configured to provide an outflow of the liquid coolant from the second longitudinal portion of the interior.

17. The electronic device of claim 16, wherein the inlet and outlet openings of each of the heat sink bodies are disposed at one end of the respective heat sink body.

18. The electronic device of claim 17, wherein each of the conduits interconnects the outlet opening of one of the heat sink bodies with the inlet opening of an adjacent heat sink body.

19. The electronic device of claim 10, wherein the electronic device is a network switch device.

20. An electronic device comprising:
a plurality of receptacle cages, each of the receptacle cages comprising a longitudinal opening extending along a portion of a top surface thereof;
a plurality of heat sink bodies configured to contain a liquid coolant, each of the heat sink bodies covering the longitudinal opening of one of the receptacle cages and being configured to contact a form factor device when the form factor device is received within the respective receptacle cage; and
a plurality of conduits interconnecting the heat sink bodies.
